(19) United States
(12) Patent Application Publication
(10) Pub. No.: US 2014/0036196 A1
(43) Pub. Date: Feb. 6, 2014

(54) LCD Display, Backlight module, and Back Plate Component Thereof

(71) Applicants: Yu-chun Hsiao, Shenzhen (CN); Weifeng Chen, Shenzhen (CN)

(72) Inventors: Yu-chun Hsiao, Shenzhen (CN); Weifeng Chen, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/641,113

(22) PCT Filed: Aug. 9, 2012
(86) PCT No.: PCT/CN2012/079880

§ 371 Date: Oct. 13, 2012

(30) Foreign Application Priority Data
Jul. 31, 2012 (CN) 201210270282.8

(51) Int. Cl. H05K 7/20; H05K 7/18; G02F 1/1335

(52) U.S. Cl. CPC H05K 7/20; G02F 1/133608; H05K 7/18
USPC 349/58; 362/621; 211/26.2

(57) ABSTRACT

The present invention discloses an LCD display device, a backlight module and a back plate component thereof. The had plate component includes a movable part and an arm part. The movable part includes a loading part and an erection part, where the loading part is used for loading the light guiding plate and comprises a first guiding part, and the erection part is used for setting up the light source. The arm part includes a second guiding part. The movable part and the arm part are allowed to slide oppositely through the coordination of the first guiding part and the second guiding part such that the light source is allowed to slide near or away the arm part.

### BACKGROUND OF THE INVENTION

1. Field of the Invention

The invention relates to an LCD, and more particularly, to a backlight module, back plate component, and an LCD display using the backlight module.

2. Description of the Prior Art

In the related art, most of backlight modules use supporting member having holes in it to support the light guiding plate. Furthermore, other parts are used to fix the light guiding plate and the back plate component, and then the assembled backlight module are utilized inside the LCD display device.

Unfortunately, the supporting member often curves due to its insufficient rigidity. This causes the backlight component to push the light guiding plate such that the light conduct plate twists, also. In this way, the performance of the backlight module is also ruined.

### SUMMARY OF THE INVENTION

It is therefore one of the primary objectives of the claimed invention to provide an LCD display device, a backlight module, and back plate component thereof, capable of solving the problem of above-mentioned curved light guiding plate due to the insufficient rigidity of the back plate component.

According to the present invention, an LCD display device comprises an LCD panel, a backlight module comprising a light source and a light guiding plate, and a back plate component used in the backlight module. The back plate component comprises: a movable part, comprising a loading part and an erection part, where the loading part is used for loading the light guiding plate and comprises a first guiding part, and the erection part is used for setting up the light source; and an arm part, the arm part comprising a second guiding part, where the movable part and the arm part are allowed to slide oppositely through the coordination of the first guiding part and the second guiding part such that the light source is allowed to slide near or away the arm part. The erection part has a first supporting part, one side of the movable part has a second supporting part, and the LCD panel is fixed on the first supporting part and the second supporting part. The first guiding part is a bulge and the second guiding part is a guiding trench, or the first guiding part is a guiding trench and the second guiding part is a bulge, or the first guiding part and the second guiding part are both guiding trenches where a rivet or a slide passes through the first guiding part and the second guiding part.

In one aspect of the present invention, the first guiding part and the second guiding part are multiple, and the first guiding parts correspond to the second guiding parts one-by-one.

In another aspect of the present invention, the bulge is a rivet fixedly set up on the loading part, or the bulge is formed integrally with the loading part.

In still another aspect of the present invention, the arm part comprises a first support and a second support, the first support and the second support are connected through a fixed member, the movable part comprises a first movable member and a second movable member, respectively set up on the opposite ends of the arm part, and the first movable member and the second movable member are allowed to slide near or away each other along the arm part through the coordination of the first guiding part and the second guiding part.

In yet another aspect of the present invention, the movable part is manufactured with heat-dissipation material, the movable part has a side part vertical to the erection part, and the side part and the erection part coordinate to form a positioning trench to fix the light guiding plate.

According to the present invention, a back plate component used in a backlight module is provided. The back plate unit comprises: a movable part, comprising a loading part and an erection part, where the loading, part is used for loading the light guiding plate and comprises a first guiding part, and the erection part is used for setting up the light source; and an arm part, the arm part comprising a second guiding part, where the movable part and the arm part are allowed to slide oppositely through the coordination of the first guiding part and the second guiding part such that the light source is allowed to slide near or away the arm part.

In one aspect of the present invention, the first guiding part is a bulge and the second guiding part is a guiding trench, the bulge is engaged with the guiding trench to allow the bulge sliding along the guiding trench.

In another aspect of the present invention, the first guiding part and the second guiding part are multiple, and the first guiding parts correspond to the second guiding parts one-by-one, the bulge is a rivet fixedly set up on the loading part, or the bulge is formed integrally with the loading part.

In another aspect of the present invention, the first guiding part is a guiding trench and the second guiding part is a bulge, the bulge is engaged with the guiding trench to allow the bulge sliding along the guiding trench.

In another aspect of the present invention, the first guiding part and the second guiding part are multiple, and the first guiding parts correspond to the second guiding parts one-by-one, the bulge is a rivet fixedly set up on the loading part, or the bulge is formed integrally with the loading part.

In another aspect of the present invention, the first guiding part and the second guiding part are both guiding trenches where a rivet or a slide passes through the first guiding part and the second guiding part.

In another aspect of the present invention, the first guiding part and the second guiding part are multiple, and the first guiding parts correspond to the second guiding parts one-by-one.

In sill another aspect of the present invention, the arm part comprises a first support and a second support placed between a width, the first support and the second support are connected through a fixed member, the movable part comprises a first movable member and a second movable member, respectively set up on the opposite ends of the arm part, and the first movable member and the second movable member are allowed to slide near or away each other along the arm pan through the coordination of the first guiding part and the second guiding part.

In yet another aspect of the present invention, the movable part is manufactured with heat-dissipation material, the movable part has a side part vertical to the erection part, and the side part and the erection part coordinate to form a positioning trench to fix the light guiding plate.

According to the present invention, a backlight module comprises a light source, a light guiding plate, and a back plate unit. The back plate unit comprises: a movable part, comprising a loading part and an erection part, where the loading part is used for loading the light guiding plate and comprises a first guiding part, and the erection part is used for setting up the light source; and an arm part, the arm part comprising a second guiding part, where the movable part and the arm part are allowed to slide oppositely through the coordination of the first guiding part and the second guiding part such that the light source is allowed to slide near or away the arm part. The light source is disposed on a side of the light guiding plate near the erection part, and the light guiding plate is disposed on the movable part.

In one aspect of the present invention, the first guiding part is a bulge and the second guiding part is a guiding trench, or the first guiding part is a guiding trench and the second guiding part is a bulge, or the first guiding part and the second guiding part are both guiding trenches where a rivet or a slide passes through the first guiding part and the second guiding part.

According to an exemplary embodiment of the present invention, an LCD display device, a backlight module, and a back plate component are disclosed. A guiding part is set up on movable part of the back plate component, a second guiding part is set up on the arm part of the back plate component, and the light guiding plate is placed on the movable part. Through the above-mentioned mechanism, when the arm becomes curved due to insufficient rigid, it forces the movable part to push the light guiding plate. The revered power of the light guiding plate will push the movable part to make the light guiding plate slide away the arm part through the coordination of the first guiding part and the second guiding part. Therefore, the light guiding plate can prevent from being curved.

BRIEF DESCRIPTION OF THE DRAWINGS

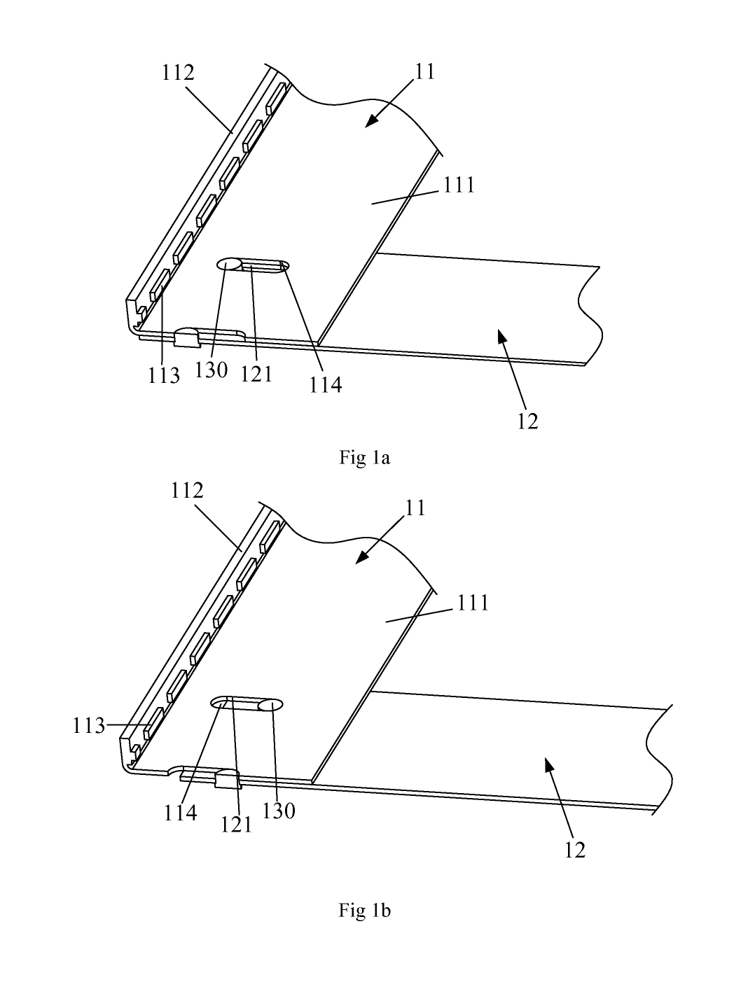

FIG. 1a is a diagram showing a part of the back plate component according to a first embodiment of the present invention.

FIG. 1b is a diagram showing the coordination of the back plate component shown in FIG. 1a When the arm part becomes curved.

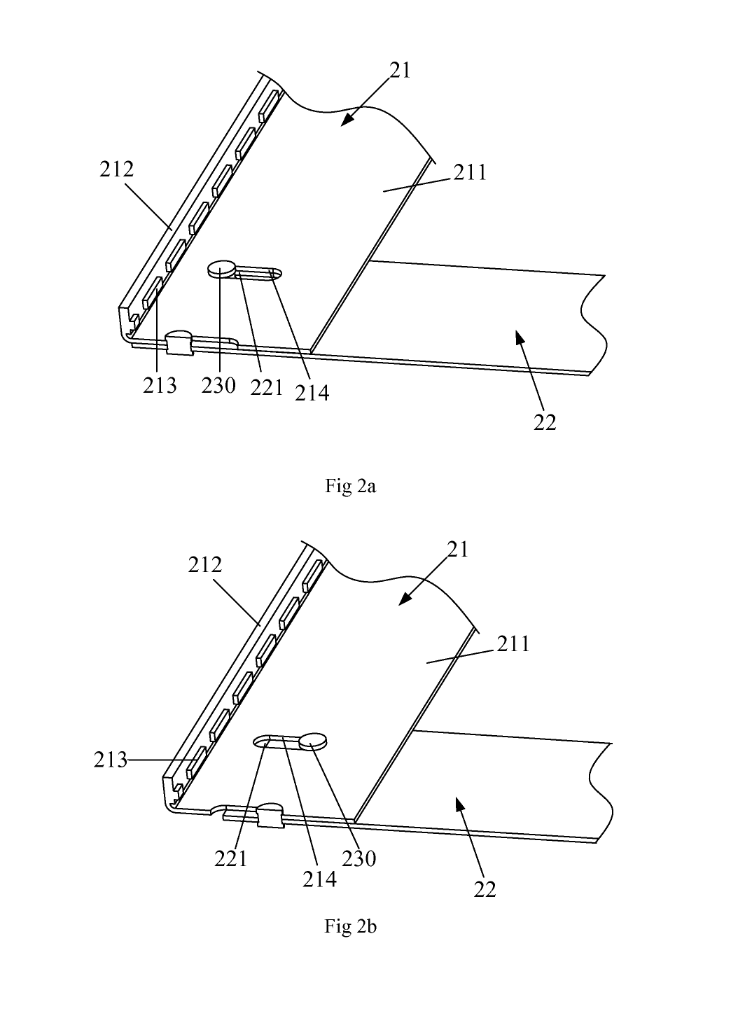

FIG. 2a is a diagram showing a part of the back plate component according to a second embodiment of the present invention.

FIG. 2b is a diagram showing the coordination of the back plate component shown in FIG. 2a when the arm part becomes curved.

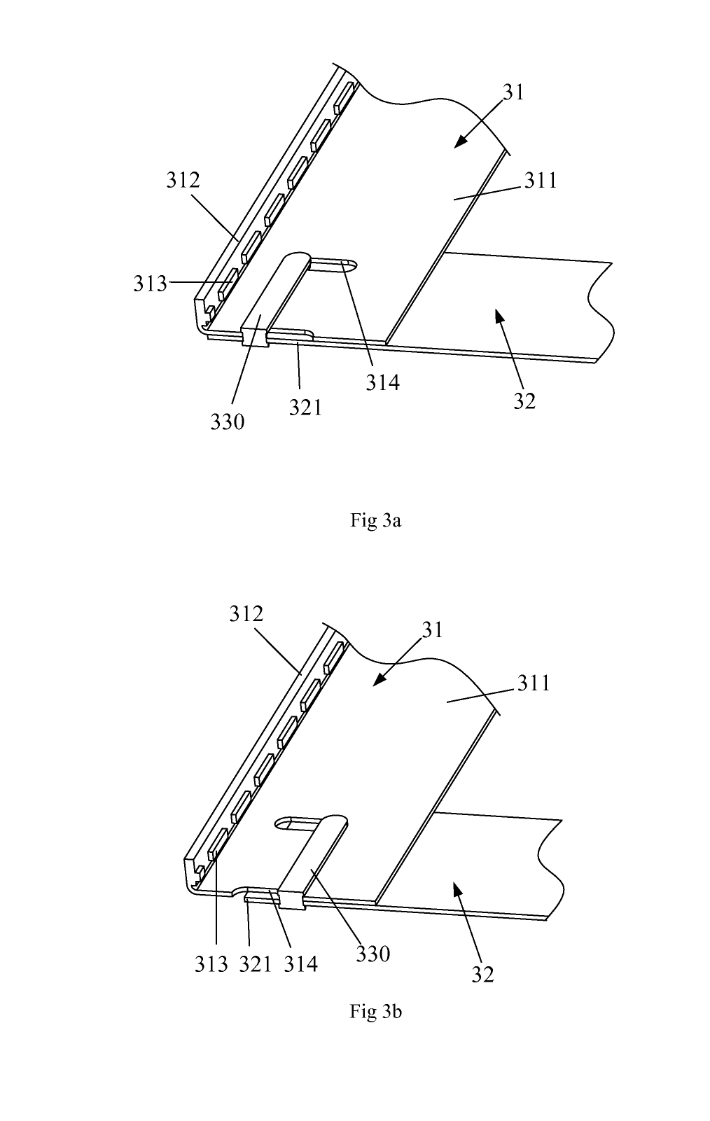

FIG. 3a is a diagram showing a part of the back plate component according to a third embodiment of the present invention.

FIG. 3b is a diagram showing the coordination of the back plate component shown in FIG. 3a when the arm part becomes curved.

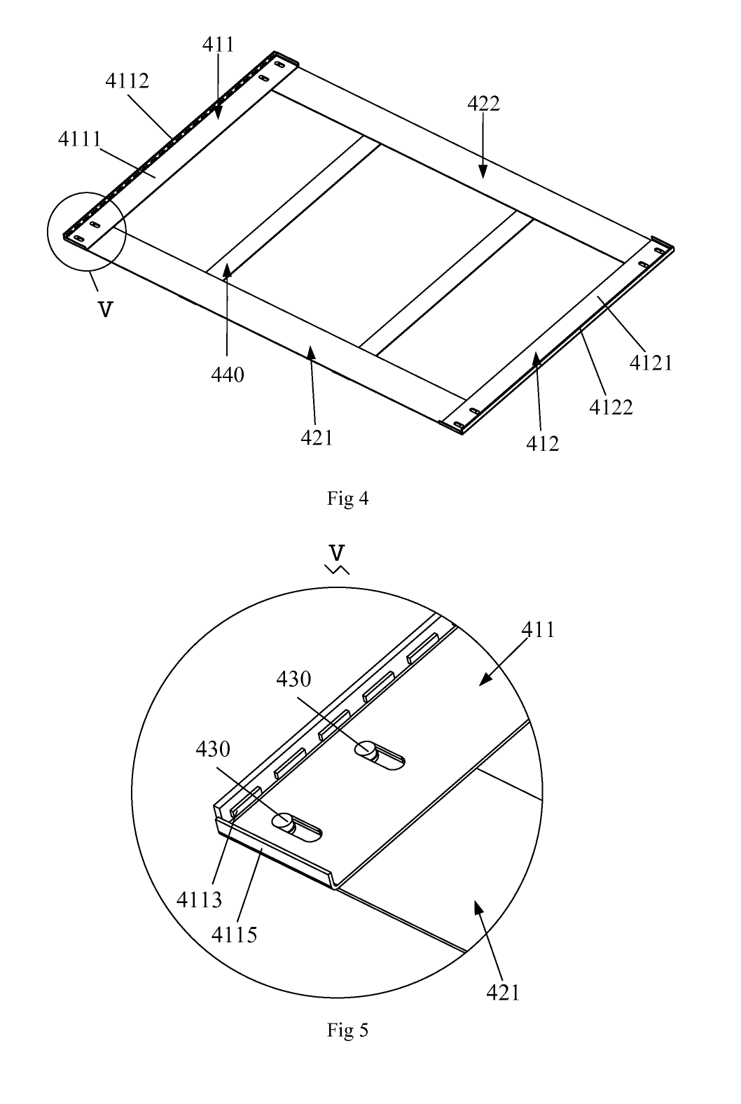

FIG. 4 is a diagram showing a back plate component according to an embodiment of the present invention.

FIG. 5 is an enlarged diagram showing the V part of the back plate component.

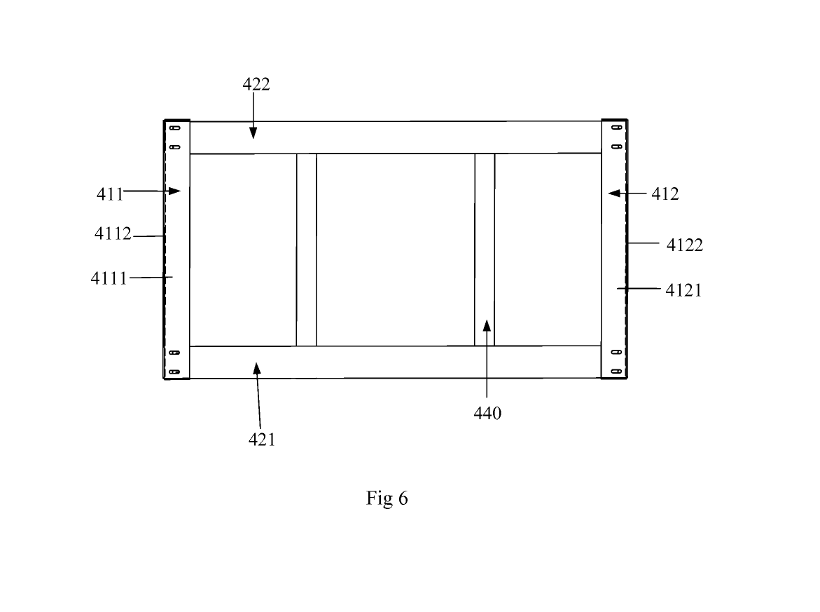

FIG. 6 is a diagram showing the front view of the back plate component.

### DETAILED DESCRIPTION OF THE PREFERRED EMBODIMENT

These and other objectives of the claimed invention will no doubt become obvious to those of ordinary skill in the art after reading the following detailed description of the preferred embodiment that is illustrated in the various figures and drawings.

### Embodiment 1

Please refer to FIG. 1a and FIG. 1b. FIG. 1a is a diagram showing a part of the back plate component according to a first embodiment of the present invention. FIG. 1b is a diagram showing the coordination of the back plate component shown in FIG. 1a when the arm part becomes curved.

Please note, in this embodiment, the back plate component includes, but not limited to, the movable part 11 and the arm part 12.

Preferably, the movable part 11 is manufactured with a heat-dissipation material to improve the heat-dissipation effect of the backlight module. But in the actual implementation, the material of the movable part 11 can be determined according to the demanded heat-dissipation effect of the backlight module and the structure design of the back plate component. The heat-dissipation material is regarded as an example, not a limitation of the present invention.

Specifically, the movable part 11 comprises a loading part 111, an erection part 112, a light source 113, and one or multiple first guiding parts 114. The loading part 111 is used for loading the lighting components of the backlight module, such as the light conducing plate. The width of the loading part 111 can be determined according to its rigidity. For example, if the rigidity is not enough, a wider width is needed to improve the supporting effect to the light guiding plate. On the contrary, if the rigidity of the loading part 111 is good, a smaller width is needed to support the light guiding plate in order to reduce the material of the back plate component.

The erection part 112 can be placed in the direction vertical to the loading part 111 The light source 113 is set up on the inner wall of the erection part 112, where the light source 113 can be one or multiple. The number of the light source 113 can be determined according to the design of the backlight module, and is not limited in the present invention. The first guiding part 114 can be designed as a guiding trench.

For simplicity, FIG. 1a only depicts the structure of one end of the movable part 11. The structures of the other ends of the movable part 11 are similar to the end shown in FIG. 1a, and further illustration is thus omitted here.

Correspondingly, the arm 12 has one or multiple second guiding parts 121. The second guiding parts 121 can be designed as a guiding trench, and the opening of the second guiding part 121 can be designed to be matched to the opening of the first conducting part 114. The back plate component further comprises a rivet 130 jointed on the arm part 12. The diameter of the rivet 130 is matched to the openings of the first guiding part 114 and second guiding part 121 such that the rivet 130 is allowed to slide inside the first guiding part 114 and the second guiding part 121. This makes it possible for the movable pan 11 and the arm part 12 to connect to each other with the capability of sliding oppositely.

Surely, the first guiding part 114 can be designed as a bulge. To speak more specifically, the first guiding part can be a rivet fixedly placed on the movable part 11, or cart be manufactured with the movable part 11. The second guiding part 121 cart be designed correspondingly as a guiding trench. The size of the opening of the guiding trench (second guiding part 121) is matched to the width of the bulge (the first guiding part 114). The first guiding part 114 is placed inside the second guiding part 121. In this way, the movable part 11 and the arm part 12 are connected with the capability of sliding oppositely through the coordination of the first guiding part 114 and the second guiding part 121. Therefore, the light source 113 can slide away or near the arm part 12.

Furthermore, in this embodiment, the first guiding part 114 can be designed as a trench, and the second guiding part 121 can be designed correspondingly as a rivet fixedly placed on the arm part 12 or can be manufactured with the arm part 12. The second guiding part 121 can be designed correspondingly as a guiding trench. The size of the opening of the guiding trench (first guiding part 114) is matched to the width of the bulge (the second guiding part 121). The second guiding part 121 is placed inside the first guiding part 114. In this way, the movable part 11 and the arm part 12 are connected with the capability of sliding oppositely through the coordination of the first guiding part 114 and the second guiding part 121. Therefore, the light source 113 can slide away or near the arm part 12.

Please refer to FIG. 1a in conjunction with FIG. 1b. In the following disclosure, the reason why the present invention back plate component can prevent the light guiding plate from being curved is illustrated. When the backlight module is being used, the arm pan 12 may become curved due to its insufficient rigidity. When the arm part 12 become curved, the middle part of the arm part 12 moves away the movable part 11 and the one end or the arm part 12 near the movable part 11 is curved to move to the middle part of the art part 12. The curved art part 12 makes the movable part 11 curved as much as the art part 12. In this way, the light source 113 set up on the erection part 112 pushes the light guiding plate and gives the light guiding plate a force. The light guiding plate gives a reversed force to the light source 113. The reversed force pushes the movable part 11 moves away from the arm part 112. Therefore, the light source 113 starts to move away from the arm part 12 until the light source 113 stops pushing the light guiding plate. The slide 30 moves from one end of the first guiding part 114 and the second guiding part near the erection part 112 to the other end far away from the erection part 112.

In this embodiment, the present invention places the first guiding part 114 on the movable part 11, places the second guiding part 121 on the arm part 12, and places the light guiding plate on the movable part 11. Therefore, when the arm part 12 becomes curved due to insufficient rigidity, the arm part 12 makes the movable part 11 push the light guiding plate. The light guiding plate gives a reversed force to push the movable part 11. Through the coordination of the first guiding part 114 and the second guiding part 121, the movable part 11 can slide away from the arm pan 112 such that the light guiding plate can prevent from being curved.

### Embodiment 2

Please refer to FIG. 2a in conjunction with FIG. 2b. FIG. 2a is a diagram showing a part of the back plate component according to a second embodiment of the present invention. FIG. 2b is a diagram showing the coordination of the back plate component shown in FIG. 2a when the arm part becomes curved.

Please note, in this embodiment, the back plate component includes, but not limited to, the movable part 21 and the arm part 22.

Specifically, the movable part 21 comprises a loading part 211, an erection part 212, a light source 213, and a first guiding part 24. A second guiding part 221 is set up on the arm part 22. Please note, the first guiding part 214 and the second guiding part 221 can ne a combination of the above-mentioned bulge or trench, and thus omitted here.

It should be noted that the difference between the first embodiment and second embodiment is that the second embodiment utilizes the connecting member 230 such as a bulge, a rivet or slide. Furthermore, the connecting member 230 is a slide having an “H” shape cross-section. The areas of two ends of the connecting member 230 horizontal to the direction of the loading part are larger than the area of the middle part of the connecting member 230. The size of the middle part of the connecting member 230 is matched to the first guiding part 214 and the second guiding part 221 to allow the connecting member 230 to slide inside the first guiding part 214 and the second guiding pan 221. The inner sides of the two ends of the connecting member 230 restrictedly touch the front of the loading part 22 and the bottom of the arm part 22 such that the connecting member 230 can fix the arm part 22 and the movable part 21 in a direction vertical to the loading part 221. It fixes the arm part 22 and the arm part 21 without moving vertically to the loading part. The structure, coordination, and the reason how it prevents the light guiding plate from being curved of other units of the back plate component have been illustrated in the above-mentioned first embodiment, and thus omitted here.

In this embodiment, the present invention places the first guiding part 214 on the movable part 21, places the second guiding part 221 on the arm part 22, and places the light guiding plate on the movable part 21. Therefore, when the arm part 22 becomes curved due to insufficient rigidity, the arm part 22 makes the movable part 21 push the light guiding plate. The light guiding plate gives a reversed force to push the movable part 21. Through the coordination of the first guiding part 214 and the second guiding part 221, the movable part 21 can slide away from the arm part 22 such that the light guiding plate can prevent front being curved.

### Embodiment 3

Please refer to FIG. 3a in conjunction with FIG. 3b. FIG. 3a is a diagram showing, a part of the back plate component according to an embodiment of the present invention. 3b is a diagram showing the coordination of the back plate component shown in FIG. 3a when the arm part becomes curved.

Please note, in this embodiment, the back plate component includes, but not limited to, the movable part 31 and the arm part 32.

Specifically, the movable part 31 comprises a loading part 311, an erection part 312, a light source 313, and a first guiding pan 34. A second guiding part 321 is set up on the arm part 32. Please note, the first guiding part 314 and the second guiding part 321 can be a combination of the above-mentioned bulge or trench, and thus omitted here.

It should be noted that the difference between the second embodiment and third embodiment is that in this embodiment, the upper pan of the connecting member 330 is a square plate and two cylinder protrusions are connected to the square plate. The middle parts of cylinder protrusions have a diameter matched to the openings of the first guiding part 314 and the second guiding part 321 to allow the connecting member 330 to slide inside the first guiding part 314 and the second guiding part 321. The diameter of the bottom of the cylinder protrusions is slightly larger than the openings of the first guiding part 314 and the second guiding part 321. When the connecting member 330 is being assembled, the middle parts of the cylinder protrusions are through the first guiding part 314 and the second guiding part 321, and the bottoms of the cylinder protrusions restrictedly touch the arm part 32. The bottom of the square plate restrictedly touch the loading part 310 to fix the arm part 32 and movable part 31 in the direction vertical to the arm part 32. It fixes the arm part 32 and the arm part 31 without moving vertically to the arm part 32. Please note, the actual shape of the connecting member 330 and the coordination of the arm part 32 and the movable part 31 can be determined according to the design of the backlight module, and detailed illustrations are omitted here. The structure, coordination, and the reason how it prevents the light guiding plate from being curved of other units of the back plate component have been illustrated in the above-mentioned first embodiment, and thus omitted here.

In this embodiment, the present invention places the first guiding part 314 on the movable part 31, places the second guiding part 321 on the arm part 32, and places the light guiding plate on the movable pan 31. Therefore, when the arm part 32 becomes curved due to insufficient rigidity, the arm part 32 makes the movable part 31 push the light guiding plate. The light guiding plate gives a reversed force to push the movable part 31. Through the coordination of the first guiding part 314 and the second guiding part 321, the movable part 31 can slide away from the arm part 32 such that the light guiding plate can prevent from being curved.

Please refer to FIG. 4 to FIG. 6. FIG. 4 is a diagram showing a back plate component according to an embodiment of the present invention. FIG. 5 is an enlarged diagram showing the V part of the back plate component. FIG. 6 is a diagram showing the front view of the back plate component.

From FIG. 4, it can be seen that the actual structure of the back plate component comprises a first movable member 411, a second movable member 412, an arm part 42, a connecting member 430, and fixing member 440.

The first movable member 411 and the second movable member 412 are respectively set up on the two ends of the arm part 42. The first movable member 411 comprises a first loading part 4111, a first erection part 4112, a light source 4113, and a first guiding part. The second movable member 412 comprises a second loading part 4121, a second erection part 4122, and a second guiding part. The structures and coordination of the above-mentioned units are illustrated in the above-mentioned embodiments, and thus omitted here. The first movable member 411 and the second movable member 412 respectively further comprise an erection part 4112 and an erection part 4122. Furthermore, the first movable part 411 and the second movable part 412 both comprise a first side member 4115 and a second side member (not shown). The first side member 4115 and the second side member is placed on the edges of the first movable part 411 and the second movable part 412.

The arm part 42 further comprises a first support 421 and a second support 422, which are placed between a width. The first support 421 and the second support 422 are connected through the fixing member 440. The arm part 42 is coordinated with the movable part. Specifically, the first guiding part and the second guiding part are coordinated such that the first movable part 411 and the second movable part 412 can slide along the arm part 42 near or away from each other. The actual coordination mechanism has been illustrated in the above, and thus omitted here. The way to fix the fixing member 440 and the arm part 42 can be soldering them, manufacturing them together, or other fixing methods. The number of the fixing member 440 can be one, two or more than two. The actual number of the fixing member 440 and the fixing mechanism used for fixing the fixing member 440 and the arm part 42 can be determined according to actual design requirements, and is not a limitation of the present invention. In addition, the connecting part 430 can be the above-mentioned bulge, rivet, slide, or the combination of there units, and thus omitted here.

In the following disclosure, FIG. 4 and FIG. 5 are both used to illustrate the assembling procedure of the light guiding plate:

The bottom of light guiding plate is placed on the first loading part 4111 and the second loading part 4121. One side or the light guiding plate restrictedly touch the plane of the first erection part 4112, which is near the arm part 42. Another side adjacent to the above-mentioned side of the light guiding plate restrictedly touches the inner plane of the first side part 4115. The other sides of the light guiding plate are assembled according to the above-mentioned procedure, and thus omitted here.

According to an embodiment of the present invention, a backlight module is provided. The backlight module comprises optical components and the above-mentioned back plate component. The optical components comprise stacked light guiding plate and optical film. In general, the optical film is placed above the light guiding plate such that the light guiding plate supports the optical film. The back plate component comprises the movable part and the arm part. The supporting part of the movable part is used to support the optical components. The erection part and the side part of the movable part are used to fix the optical components. The structure of the back plate component has been illustrated in the above disclosure, and thus omitted here. Furthermore, the coordination of the back plate component and the optical components has also been illustrated in the above disclosure, and thus omitted here.

In addition, according to an embodiment of the present invention, an LCD display is provided. The LCD display comprises an LCD panel and the above-mentioned backlight module. The back plate component of the backlight module comprises the movable part and the arm part. The supporting part of the movable part is used to support the optical components. The erection part and the side part of the movable part are used to fix the optical components. The erection part has a first supporting part, and the side part has a second supporting part. The LCD is fixed by the first supporting part and the second supporting part. The structure of the back plate component has been illustrated in the above disclosure, and thus omitted here.

In contrast to the related art, the present invention LCD display comprises the above-mentioned backlight module or the back plate component. Therefore, the present invention LCD display can prevent the light guiding plate from being curved such that using effect of the backlight module is improved.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An LCD display device, comprising an LCD panel, a backlight module comprising a light source and a light guiding plate, and a back plate component used in the backlight module, the back plate component comprising:
a movable part, comprising a loading part and an erection part, where the loading part is used for loading the light guiding plate and comprises a first guiding part, and the erection part is used for setting up the light source; and
an arm part, the arm part comprising a second guiding part, where the movable part and the arm part are allowed to slide oppositely through the coordination of the first guiding part and the second guiding part such that the light source is allowed to slide near or away the arm part;
wherein the erection part has a first supporting part, one side of the movable part has a second supporting part, and the LCD panel is fixed on the first supporting pan and the second supporting part;
wherein the first guiding part is a bulge and the second guiding part is a guiding trench, or the first guiding part is a guiding trench and the second guiding part is a bulge, or the first guiding part and the second guiding part are both guiding trenches where a rivet or a slide passes through the first guiding part and the second guiding part.

2. The LCD display device according to claim 1, wherein the first guiding part and the second guiding part are multiple, and the first guiding parts correspond to the second guiding parts one-by-one.

3. The LCD display device according to claim 1, wherein the bulge is a rivet fixedly set up on the loading part, or the bulge is formed integrally with the loading part.

4. The LCD display device according to claim 1, wherein the arm part comprises a first support and a second support, the first support and the second support are connected through a fixed member, the movable part comprises a first movable member and a second movable member, respectively set up on the opposite ends of the arm part, and the first movable member and the second movable member are allowed to slide near or away each other along the arm part through the coordination of the first guiding part and the second guiding part.

5. The LCD display device according to claim 1, wherein the movable part is manufactured with heat-dissipation material, the movable part has a side part vertical to the erection part, and the side part and the erection part coordinate to form a positioning trench to fix the light guiding plate.

6. A back plate component used in a backlight module, the back plate unit comprising:
a movable part, comprising a loading part and an erection part, where the loading part is used for loading the light guiding plate and comprises a first guiding part, and the erection part is used for setting up the light source; and
an arm part, the arm part comprising a second guiding part, where the movable part and the arm part are allowed to slide oppositely through the coordination of the first guiding, part and the second guiding part such that the light source is allowed to slide near or away the arm part.

7. The back plate component according to claim 6, wherein the first guiding part is a bulge and the second guiding part is a guiding trench, the bulge is engaged with the guiding trench to allow the bulge sliding along the guiding trench.

8. The back plate component according to claim 7, wherein the first guiding part and the second guiding part are multiple, and the first guiding parts correspond to the second guiding parts one-by-one, the bulge is a rivet fixedly set up on the loading part, or the bulge is formed integrally with the loading part.

9. The back plate component according to claim 6, wherein the first guiding part is a guiding trench and the second guiding part is a bulge, the bulge is engaged with the guiding trench to allow the bulge sliding along the guiding trench.

10. The back plate component according to claim 9, wherein the first guiding part and the second guiding part are multiple, and the first guiding parts correspond to the second guiding parts one-by-one, the bulge is a rivet fixedly set up on the loading part, or the bulge is formed integrally with the loading part.

11. The back plate component according to claim 9, wherein the first guiding part and the second guiding part are both guiding trenches where a rivet or a slide passes through the first guiding part and the second guiding part.

12. The back plate component according to claim 11, wherein the first guiding part and the second guiding part are multiple, and the first guiding parts correspond to the second guiding parts one-by-one.

13. The back plate component according to claim 6, wherein the arm part comprises a first support and a second support placed between a width, the first support and the second support are connected through a fixed member, the movable part comprises a first movable member and a second movable member, respectively set up on the opposite ends of the arm part, and the first movable member and the second movable member are allowed to slide near or away each other along the arm part through the coordination of the first guiding part and the second guiding part.

14. The back plate component according to claim 6, wherein the movable part is manufactured with heat-dissipation material, the movable part has a side part vertical to the erection part, and the side part and the erection part coordinate to form a positioning trench to fix the light guiding plate.

15. A backlight module comprising a light source, a light guiding plate, and a back plate unit, the back plate unit comprising:
a movable part, comprising a loading part and an erection part, were the loading part is used for loading the light guiding plate and comprises a first guiding part, and the erection part is used for setting up the light source; and
an arm part, the arm part comprising a second guiding part, where the movable part and the arm part are allowed to slide oppositely through the coordination of the first guiding part and the second guiding part such that the light source is allowed to slide near or away the arm part,
wherein the light source is disposed on a side of the light guiding plate near the erection part, and the light guiding plate is disposed on the movable part.

16. The backlight module according to claim 6, wherein the first guiding part is a bulge and the second guiding part is a guiding trench, or the first guiding part is a guiding trench and the second guiding part is a bulge, or the first guiding part and the second guiding part are both guiding trenches where a rivet or a slide passes through the first guiding part and the second guiding part.
